(19) United States
(12) Patent Application Publication
(10) Pub. No.: US 2025/0210472 A1
(43) Pub. Date: Jun. 26, 2025

(54) SEMICONDUCTOR PACKAGE, POWER SEMICONDUCTOR MODULE AND MANUFACTURING PROCESS

(71) Applicant: ZF Friedrichshafen AG, Friedrichshafen (DE)

(72) Inventors: Sebastian Besold, Neudrossenfeld (DE); Marc Rasch, Immenstaad (DE)

(73) Assignee: ZF Friedrichshafen AG, Friedrichshafen (DE)

(21) Appl. No.: 18/989,943

(22) Filed: Dec. 20, 2024

(30) Foreign Application Priority Data
Dec. 22, 2023 (DE) 10 2023 213 257.5

(51) Int. Cl. H01L 23/495; H01L 21/56; H01L 23/00; H01L 23/31

(52) U.S. Cl. CPC H01L 23/49537; H01L 21/56; H01L 23/3121; H01L 24/32; H01L 2224/32245

(57) ABSTRACT

A semiconductor package for a power semiconductor module in a power converter has a power semiconductor with a first side, an opposing second side, and a control terminal on the first side, a first contact unit for obtaining contact to the first side, wherein the first contact unit is in thermal and electrical contact with a majority of the surface of the first side, a second contact unit for obtaining contact to the second side, wherein the second contact unit is in thermal and electrical contact with a majority of the surface of the second side, and a terminal connector for connecting the control terminal on the power semiconductor to a control unit. A power semiconductor module for a power converter and a method for the production of numerous semiconductor packages are also disclosed.

### CROSS-REFERENCE TO RELATED APPLICATION

This application claims priority to German Patent Application No. 10 2023 213 257.5, filed on Dec. 22, 2023, the entirety of which is hereby fully incorporated by reference herein.

### TECHNICAL FIELD

The present disclosure relates to a semiconductor package for a power semiconductor module in power converter. The present disclosure also relates to a power semiconductor module for a power converter and a method for the production of such a semiconductor package.

### BACKGROUND

The power electronics in electric and hybrid vehicles conducts electricity from the battery to the electric motor, converting direct current into alternating current. This requires an AC converter, or an inverter. Numerous transistors or other power semiconductors are normally used for this, which are combined to obtain a power semiconductor module, which switches on and off quickly at regular intervals. In particular, MOSFETs (metal-oxide, semiconductor field effect transistors) and IGBTs (insulated-gate bipolar transistors) are used as switches for this. When switched on, electricity is conducted from the battery to the motor (conducting phase). By switching at high frequencies, an alternating current is obtained, which can then be used by the electric motor to power the wheels of the vehicle. Numerous power semiconductors are usually connected in parallel in a (topological) switch to increase the conductive capacity.

The production process for these power semiconductor modules normally comprises various technologically difficult steps. The individual power semiconductors (chips or semiconductor chips) are normally placed on a ceramic substrate which can also function as a heatsink. The ceramic substrate is attached with a soldering, sintering, or thermal grease process to a base plate that has a cooling structure. Contact to the drain, source, and gain terminals on the individual power semiconductors is normally obtained with a wire-bonding process. These wires are connected to the corresponding terminals on the power semiconductors to supply electricity thereto. After the connection has been established, numerous power semiconductors or a power semiconductor module are normally coated with a casting compound to obtain a semiconductor package, which can then be used as a component in a power converter.

DE 10 2022 202 254 A1 discloses a modular half bridge module composed of at least two power semiconductor modules. Each power semiconductor module has a first outer substrate, a semiconductor switch, an intermediate substrate, a diode chip, and an second outer substrate, which are stacked together in this order. The semiconductor switch is connected to a positive terminal on the first outer substrate and a negative terminal on the intermediate substrate. The diode chip is connected to an anode terminal on the second outer substrate and to a cathode terminal on the intermediate substrate. The diode chip is electrically connected in reverse parallel by the substrate to the semiconductor switch. The at least two power semiconductor modules are connected to one another to form a half bridge.

Because it is difficult to manipulate the power semiconductor, and comparatively difficult to form the contacts thereto, this production process has been complicated and there has been little room for variation. It has frequently been necessary to alter the entire production process to obtain power semiconductor modules with higher or lower capacities, other shapes, or a different number of individual power semiconductors in a module. This increases costs, and results in lower efficiency and poor scalability.

### SUMMARY

Based on this, an object of the present disclosure is to create a method for efficiently producing a component that can be used in a flexible manner for power semiconductors and power semiconductor modules in a power converter. In particular, this should result in a highly efficient production at low costs, as well as flexibility with regard to the necessary form thereof.

A first aspect of this problem is achieved with the present disclosure by a semiconductor package for a power semiconductor module in a power converter that has:
a power semiconductor with a first side and an opposing second side, with a control terminal on the first side;
a first contact unit for the first side, which is in thermal and electrical contact with the majority of the surface of the first side;
a second contact unit for the second side, which is in thermal and electrical contact with the majority of the surface of the second side; and
a terminal connector for connecting the control terminal on the power semiconductor to a control unit.

Another aspect of the present disclosure relates to a power semiconductor for a power converter that contains numerous semiconductor packages, as described above.

A further aspect of the present disclosure relates to a method for the production of numerous semiconductor packages, as described above, comprising the steps:
provision of a support structure made of electrically and thermally conductive materials;
populating the support structure with numerous power semiconductors, and obtaining electrical and thermal contact on the second sides of the numerous power semiconductors to the support structure;
dividing the support structure into numerous semiconductor packages with at most two power semiconductors, preferably just one; and
determining an electrical parameter for each of the semiconductor packages in a testing process, and sorting the semiconductor packages based on their parameters.

Preferred embodiments of the disclosure are described herein. It is understood that the features specified above and explained below can be used not only in the given combinations, but also in other combinations or in and of themselves, without abandoning the framework of the present disclosure. In particular, the semiconductor packages, power semiconductor modules, and the method for producing numerous semiconductor packages can be realized in accordance with the embodiments of the semiconductor packages described herein.

Thermal and electrical contact can be made to both sides of the power semiconductors with the present disclosure. The first side of the power semiconductor (upper surface) can form the drain or source terminal. The first contact unit is therefore used to conduct (high) current to and from the power semiconductor, and to dissipate heat generated by switching. The second side of the power semiconductor (lower surface) can then form the source or drain terminal, respectively, and is also used to conduct (high) current to and from the power semiconductor, and to dissipate heat.

The two contact units are each in contact with a majority of the surface on the first and second sides of the power semiconductors. This results in good electrical and thermal contact. High currents can be conducted therewith, and heat can be efficiently dissipated. Losses are minimized. The current flow, unlike in prior approaches, is basically perpendicular to the surface of the power semiconductor.

The control terminal on the power semiconductor (gate terminal) is connected by a terminal connector. The control terminal is on the first side of the power semiconductor according to the present disclosure. The connection is obtained at a control unit (not part of the semiconductor package). The control unit can be used to control, or switch, the power semiconductor. By way of example, the control unit can be in the power semiconductor module, or centrally located in the power converter.

The power semiconductor module obtained with the present disclosure is designed specifically for use in a power converter for a vehicle. The DC voltage from a battery is converted to AC voltage for an electric motor in this power converter. Comparatively high currents are switched on an off for this. This requires numerous semiconductor packages connected in parallel.

The semiconductor package obtained with the present disclosure is a chip scaled/sized package (CSP). The semiconductor package is basically an attempt at reducing to just the essential and obtaining the smallest possible unit for a power semiconductor.

Unlike previous attempts to create power semiconductor modules, or package power semiconductors, no electrical insulating layers are needed or used in the semiconductor packages obtained with the present disclosure, particularly on the upper and lower surfaces of the power semiconductors or the contact components. The semiconductor package obtained with the present disclosure therefore forms the smallest possible component, reduced to just the essentials. Eliminating the (electrical) insulating layers often results in better heat dissipation, because these insulating layers can also obstruct heat dissipation.

The semiconductor package obtained with the present disclosure can also be processed more efficiently. In particular, different power semiconductor modules can be produced with the semiconductor packages, in particular with regard to performance and shape. This makes it easier to adapt them for higher performance or to conform to a necessary shape. This results in a more flexible production. The semiconductor packages can be produced easily. The production can also be readily scaled to specific needs.

In particular, the power semiconductor module can have a three-dimensional structure. In other words, the semiconductor packages can also be stacked to some extent, resulting in more efficient electrical conductivity.

The semiconductor package in a preferred embodiment has no more than two power semiconductors. This semiconductor package can also be encased in a casting compound. Because no more than two, ideally just one, power semiconductors are used in a semiconductor package, the package size is as small as possible. This maximizes the flexibility in terms of its use. This also results in further advantages in the production process, e.g. there is no need for a tedious sorting of the unprocessed power semiconductors. Use of a casting compound results in a robust semiconductor package. Either a hard or soft casting compound can be used. It is understood that the contact points and terminal connectors protrude therefrom, in order to be able to connect electrical or signal conductors.

The first contact unit in a preferred embodiment is a metallic layer, preferably made of copper, or a rigid block made of copper. The second contact unit can also be rigid, preferably in the form of a copper substrate. The first contact unit can be a rigid component made of an electrically and thermally conductive material. Rigid components form reliable contacts. They also make the production process more efficient. The second contact unit can be a lead frame. By using a rigid component, the production process is more efficient, and the result is mechanically robust.

In the preferred embodiment, the first contact unit is in contact with at least 60%, preferably at least 70%, particularly preferably at least 80% of the surface on the first side of the power semiconductor. The second contact unit can also be in contact with the entire surface on the second side of the power semiconductor. Contact to a majority of a surface area means contact with more than half of the surface area. Preferably the contact area is greater, and extends over more of the surface on the first and second sides of the power semiconductor. In particular, it is possible for the second contact unit to be in contact with all of the second side of the power semiconductor. Slightly less thermal and electrical contact on the first side is acceptable, in order to also be able to connect to the control terminal. This results in an efficient production with good electrical and thermal properties.

In a preferred embodiment, the terminal connector comprises a flexible printed circuit board with conductor paths. Other conductor paths can also be formed on the flexible printed circuit board, e.g. for an external Kelvin source terminal for the power semiconductor. Using a flexible printed circuit board for the terminal connector results in a more efficient production process. This also results in a more mechanically robust product. Moreover, further possibilities with regard to the use of other components such as a sensor are also obtained.

In a preferred embodiment, there is a sintered bond between the first contact unit and first side of the power semiconductor, and/or between the second contact unit and the second side of the power semiconductor. In particular, sintering can be used to create the bond. This results in a mechanically robust component with electrical and thermal conductivity advantages. Moreover, the production process is more efficient, because it is possible to work with high temperatures with a sintered bond.

In a preferred embodiment, the cross section of the first contact unit parallel to a plane of the power semiconductor is smaller where it comes in contact with the first contact unit than where it is further away. This change in the size of the cross section is preferably discrete. Increasing the size of the cross section further away from the surface, or first side, of the power semiconductor improves heat dissipation. This therefore improves the efficiency of the semiconductor package in a power semiconductor module used in a power converter. The change in the size of the cross section is preferably discrete. In particular, there can be a step, where the size of the cross section changes abruptly. A step, or discrete change in the size of the cross section, can be produced efficiently. In addition, a type of recess can be obtained for the terminal connector for the control terminal on the first side of the power semiconductor.

In a preferred embodiment, the power semiconductor has another control terminal on the first side. The terminal connector preferably forms a contact between the other control terminal and the control unit. In particular, the other control terminal can be a Kelvin source terminal. This can also be connected to the control unit (which is not part of the semiconductor package), for providing and processing control signals. This further improves production efficiency for the semiconductor package. Consequently, semiconductor packages with other functions can be obtained.

The semiconductor package in a preferred embodiment does not have insulation on the first and/or second sides of the power semiconductor. In particular, the semiconductor package does not have a ceramic layer. This would form an electrical insulator that is thermally conductive. Even if an insulator, in particular a ceramic layer, is thermally conductive, it can still inhibit the thermal flux. Eliminating the insulator improves the functioning of the semiconductor package.

In a preferred embodiment of the power semiconductor module, a first half of the numerous semiconductor packages are rotated 180° in relation to the second half, such that the first contact units on the first half face in the same direction as the second contact units on the second half of the semiconductor packages. This direction is perpendicular to the plane of the (flat) power semiconductor. This means that half of the power semiconductors, or semiconductor packages, are basically inverted. This results in efficient contact. This also eliminates the need for wire bonding. As a result, the production process is more efficient.

In this context, a power semiconductor module is understood to be an assembly for use in an inverter structure, or a power converter in a vehicle. A power semiconductor, or semiconductor switch is a transistor, or chip. A topological switch is normally composed of numerous transistors. A power semiconductor module therefore contains numerous semiconductor switches or power semiconductors. A power semiconductor is a MOSFET in particular. It normally has at least one gate terminal, one source terminal, and one drain terminal, as well as, potentially, a Kelvin source terminal. Electrical and thermal contact is a connection that conducts current and heat with little resistance. Surface contact refers to a connection over a large area, or a relevant portion of an overall surface. In particular, surface contact does not make use of bond wiring.

The present disclosure shall be described and explained in greater detail below based on selected exemplary embodiments in reference to the drawings.

### BRIEF DESCRIPTION OF THE DRAWINGS

FIG. 1 shows a schematic illustration of a vehicle with a power semiconductor module according to various embodiments in a power converter;

FIG. 2 shows a schematic illustration of a power semiconductor package according to various embodiments;

FIGS. 3a and 3b show schematic illustrations of a possible use of a semiconductor package according to the present disclosure on a low side and high side of a half bridge circuit;

FIGS. 4a, 4b, 4c, and 4d show various embodiments of the semiconductor package according to various embodiments;

FIG. 5 shows a schematic illustration of an embodiment of the semiconductor package according to various embodiments, with an increase in the size of the cross section of the first contact unit;

FIG. 6 shows a schematic illustration of a semiconductor package according to various embodiments, with a terminal connector that has a flexible printed circuit board;

FIGS. 7a, 7b, 7c, and 7d show schematic illustrations of different embodiments of the semiconductor package according to various embodiments from above; and

FIG. 8 shows a schematic illustration of a method according to various embodiments for the production of numerous semiconductor packages.

### DETAILED DESCRIPTION

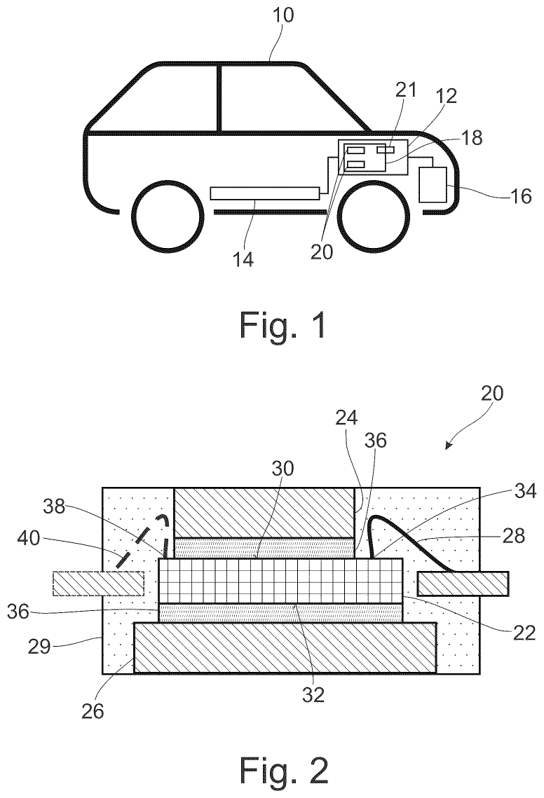

FIG. 1 is a schematic illustration of a vehicle 10 with a power converter 12. The power converter 12 is between a battery 14 and an electric machine 16 in the vehicle, for converting direct current from the battery 14 into alternating current for the electric machine 16. The power converter 12 contains a power semiconductor 18 obtained with the present disclosure, which contains numerous semiconductor packages 20 obtained with the present disclosure. There is also a control unit 21 for the various semiconductors in the semiconductor packages 20, which is connected to the gate terminals on the semiconductors. The illustration in FIG. 1 is a side view. In this exemplary embodiment, the power semiconductor module 18 contains two semiconductor packages. There are normally numerous power semiconductor modules containing numerous semiconductor packages in a power converter 12.

In accordance with various embodiments, a semiconductor package 20 in the form of a chip scaled/sized package (CSP) is used. In particular, the semiconductor package 20 preferably has no more than two individual power semiconductors (chips) and is therefore the size of a single chip, or single power semiconductor.

FIG. 2 is a schematic illustration of an embodiment of a semiconductor package 20 obtained with the present disclosure. The semiconductor package 20 contains a power semiconductor 22, a first contact unit 24, a second contact unit 26, and a terminal connector 28. The semiconductor package 20 is encased in a casting compound 29. The illustration is a sectional side view. The individual components are not drawn to scale, in particular with regard to their thickness. A power semiconductor is normally a few hundred micrometers thick. The electrical conductors are often thicker. The illustration in FIG. 2 therefore substantially illustrates the principles of the component.

The power semiconductor 22 is a substantially flat chip. The power semiconductor 22 has a first side 30, which is on top in the illustration, and a second side 32, which is on the bottom. There is a control terminal on the first side 30, in particular in the form of a gate terminal for the power semiconductor 22. A particular advantage of the present disclosure is that the semiconductor package does not need insulators. In particular, there are no electrical insulating layers needed between the first side 30 of the power semiconductor 22 and the components closer to the first contact unit 24. This results in better thermal contact and an efficient production.

The first contact unit 24 forms an electrical and thermal contact to the first side 30 of the power semiconductor 22. This is a surface contact over a majority of the first side 30. The electrical and thermal contact therefore covers at least half of the first side 30, or upper surface, of the power semiconductor 22. The first contact unit 24 preferably comes in contact with, or is connected to, more than 60%, more than 70%, or even more than 80% of the first side 30 of the power semiconductor 22. The first side 30 of the power semiconductor 22 is connected by the first contact unit 24 to a DC side or AC side of a half bridge circuit. The drain or source terminal on the power semiconductor 22 is therefore in contact with the first contact unit 24. In addition to the electrical contact, a thermal path is also obtained with the first contact unit 24 for dissipating heat generated by switching.

The second contact unit 26 is in contact with the second side 32 of the power semiconductor 22. The second contact 26 is also in thermal and electrical contact with a majority of the surface area of the second side 32 of the power semiconductor 22. Preferably, the entire second side 32 is in contact with the second contact unit 26, as shown in the illustration of the exemplary embodiment.

The first contact unit 24 is a rigid component in the illustrated exemplary embodiment. In particular, contact can be obtained through a copper block forming the first contact unit 24. Copper plating could also be used to form the first contact unit 24. By way of example, the plating can be formed through vapor deposition. The second contact unit 26 can also be a rigid component. By way of example, the second contact unit 26 can be a copper lead frame.

A sintered connection is used in the illustrated exemplary embodiment to obtain the contact between the first contact unit 24 and the power semiconductor 22, and between the second contact unit 26 and the power semiconductor 22. Soldering or some other technology can also be used.

The terminal connector 28 connects the control terminal 34 on the power semiconductor 22 to the control unit (outside the semiconductor package). In the illustrated exemplary embodiment, the terminal connector 28 comprises a bond wire. Other connecting elements can also be used.

In the illustrated exemplary embodiment, the power semiconductor 22 has an (optional) second control terminal 38, which is also on the first side 30 of the power semiconductor 22, and can be contacted externally via an (optional) second terminal connector 40. The second control terminal 38 can form a connection to a Kelvin source terminal on the power semiconductor 22. In the illustrated example, the second control terminal 38 extends outward via a second terminal connector 40, or a separate bond wire. The control terminal 34 as well as the second control terminal 38 can both be connected to the control unit by the same terminal connector. By way of example, a flexible printed circuit board with two conductor paths can be used as the (shared) terminal connector.

Compared to prior approaches, the structure of the semiconductor package 20 obtained with the present disclosure can form a CSP. This requires a minimum of components. A power semiconductor module can be obtained with numerous semiconductor packages 20. This results in a great deal of flexibility with regard to the design, because different numbers of semiconductor packages can be used. The shape of the power semiconductor module can also be altered easily, because it is not difficult to add more individual semiconductor packages.

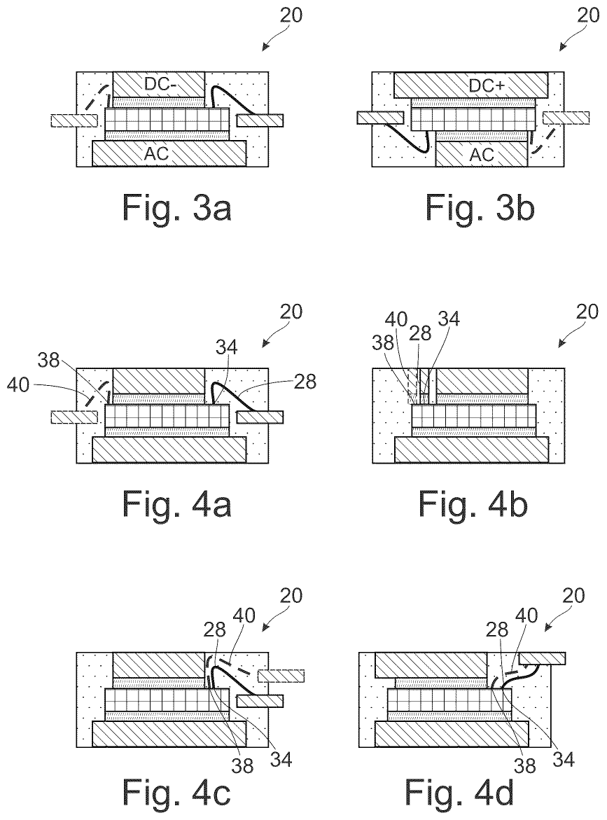

FIGS. 3a and 3b show that the semiconductor packages 20 obtained with the present disclosure can be used for a low side or high side of a half bridge circuit by rotating half of them 180°.

Reference is made to the above explanations of FIG. 2 with regard to the reference symbols in FIGS. 3a and 3b, and the following FIGS. 4a-4d, 5, 6, and 7a-7d. Identical reference symbols refer to the same components, and parts of the drawings with the same shading correspond to the same components. To avoid repetition and increase clarity, not all of the reference symbols are included in the drawings. In particular, explanations relate to differences in the embodiments and the resulting variation possibilities.

It can be derived from the illustrations in FIGS. 3a and 3b that the semiconductor packages 20 obtained with the present disclosure allow for a three-dimensional structure. In particular, they can be stacked when half of the semiconductor packages 20 used in a power semiconductor module are rotated 180°. It is understood that the semiconductor packages that are rotated 180° are otherwise identical to the other semiconductor packages. By way of example, one half of the semiconductor packages can face in the direction shown in FIG. 3a, while the other half face in the direction shown in FIG. 3b. This option results in a simplified production of power semiconductor modules composed of numerous semiconductor packages, and flexibility with regard to the shape of the power semiconductor module. This also results in an efficient production.

Different options for making contact to the control terminal 34 and the (optional) second control terminal 38 are shown in FIGS. 4a-4d. FIG. 4a shows contacts on both sides. In FIG. 4b, the contacts are at the top. In FIG. 4c, the contacts are in the middle of one side. In FIG. 4d, the contacts are on top and on one side, and the first control terminal 34 is offset toward the back in relation to the second control terminal 38 (into the depth of the illustration). The same is the case for the terminal connectors 28, 40.

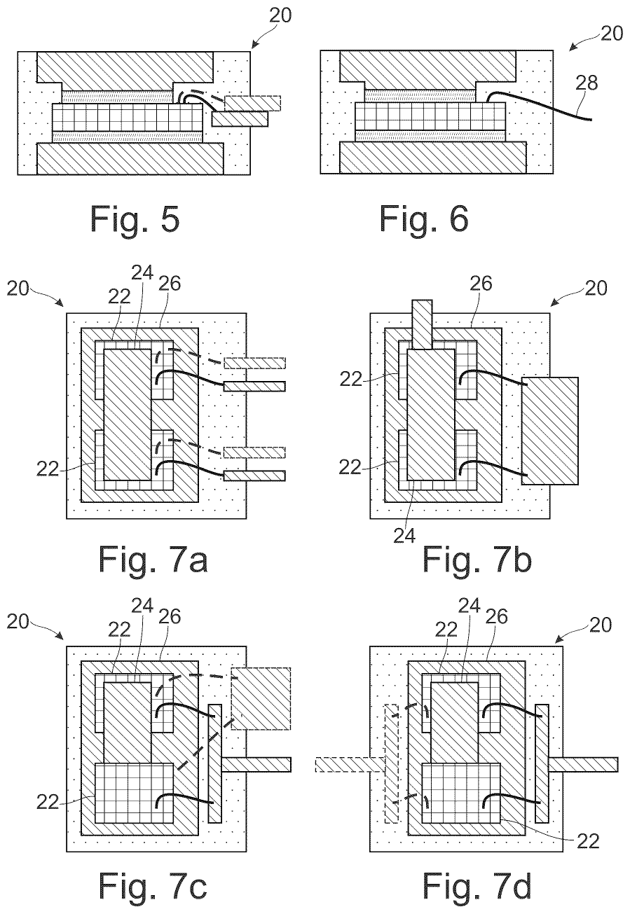

FIG. 5 shows an embodiment of the semiconductor package obtained with the present disclosure in which the size of the cross section of the first contact unit 24 on the first side 30 of the power semiconductor 22, which is parallel to a plane of the power semiconductor 22, increases further away from the first side 30 of the power semiconductor 22. The cross section of the first contact unit is thus larger, enabling better heat dissipation. In this example, the change in cross section area is obtained discretely in the form of a step. Other changes in the cross section, e.g. a smooth change, are also conceivable.

FIG. 6 shows an embodiment in which there is a terminal connector 28 in the form of a flexible printed circuit board. A conductor path can be placed thereon with forms the contact to the control terminal on the power semiconductor 22. There can also be two conductor paths, with form contacts to both the first control terminal 34 and the second control terminal 38. The terminal connector 28 can form a contact for both the first and second control terminals, in particular with two conductor paths. Moreover, other functions can also be obtained with this embodiment through additional conductor paths and other components.

Other embodiments of the semiconductor packages 20 obtained with the present disclosure are shown in FIGS. 7a-7d. These show schematic illustrations from above, whereas FIGS. 2 to 6 show sectional side views. FIGS. 7a-7d show that the semiconductor packages 20 each contain two power semiconductors 22 in these exemplary embodiments. Each pair of power semiconductors 22 can be in contact with the same first contact unit 24 and same second contact unit 26. Each of the power semiconductors 22 have a first terminal connector 28 and a second terminal connector 40, which form a contact to the first control terminal 34 and the (optional) second control terminal 28. The contacts are obtained in different ways and in different directions.

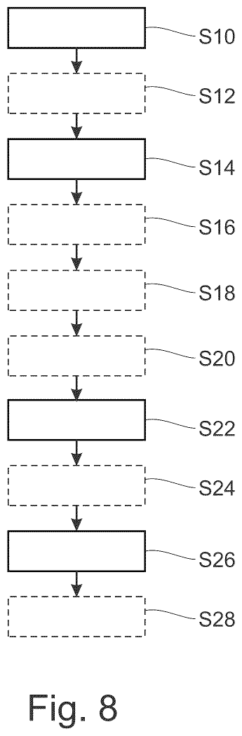

FIG. 8 shows a schematic illustration of the method obtained with the present disclosure for the production of numerous semiconductor packages. The method is for the production of semiconductor packages. As such, this method can be used in a corresponding production facility, or carried out by a corresponding production apparatus. The optional steps are not absolutely necessary for obtaining the advantages of the present disclosure. It is also possible to implement the optional steps in a different order.

The method comprises a step S10 for providing a support structure composed of an electrically and thermally conductive material, for which a lead frame panel in particular can be used.

The method comprises an (optional) step S12 for applying a sintering paste with which the power semiconductor is attached.

The method comprises a step S14 for populating a support structure with numerous power semiconductors and obtaining electrical and thermal contact at the second sides of the power semiconductors to the support structure. By way of example, a chip pick-and-place process can be used for this.

In a successive optional step S16 for establishing the upper contact to the first side of the power semiconductors, a copper block can be used for the first contact unit on each of the power semiconductors. A pick-and-place process can also be used for this. By way of example, the connection can be obtained with a sintering process.

In a successive optional step S18, the control terminals on the different power semiconductors can be connected. A wire bond process can be used for this. In particular, contact can be made to both the first and second control terminals to enable control of the power semiconductors.

In a successive step S20, a casting compound can be applied to the individual semiconductor packages.

In a successive step S22, the support structure is divided up to obtain numerous semiconductor packages with no more than two power semiconductors, preferably just one power semiconductor.

Subsequently, in an optional step S24, the individual semiconductor packages can be trimmed and shaped.

In another step S26, an electrical parameter is determined for each of the semiconductor packages in a testing process, and the semiconductor packages are sorted on the basis thereof. In particular, the testing process can be used to determine an electrical parameter. By sorting them on the basis of this electrical parameter, semiconductor packages, or power semiconductors, with the same electrical properties can be used in a power semiconductor module. The respective semiconductor packages can be selected for each power semiconductor module based on these electrical parameters. This sorting of the semiconductor packages after they have been separated out results in an improvement over the prior art, because this eliminates the need to sort them prior to placing the power semiconductors on the support structures. This prior sorting is more difficult, because the individual power semiconductors are hard to manipulate. This increases the efficiency of the production process.

In a successive optional step S28, the individual semiconductor packages can be packaged.

The present disclosure has been comprehensively described and explained in reference to the drawings. The description and explanation are to be regarded as merely exemplary, and not as limiting. The disclosure is not limited to the embodiments disclosed herein. Other embodiments or variations can be obtained by the person skilled in the art when using the present disclosure, and through a precise analysis of the drawings, the disclosure, and the claims.

The terms, “comprising” and “containing” or “with,” do not exclude the presence of other elements or steps. The indefinite articles “a” or “an” do not exclude the possibility of a plurality. A single element or unit can carry out the function of numerous units specified in the claims. An element, unit, interface, apparatus, or system can be implemented partially or entirely with hardware and/or software. Simply specifying certain measures in different dependent claims is not to be understood to mean that a combination of these measures cannot also be advantageously used. Reference symbols in the claims are not to be understood as limiting.

### REFERENCE SYMBOLS

10 vehicle
12 power converter
14 battery
16 electric machine
18 power semiconductor module
20 semiconductor package
21 control unit
22 power semiconductor
24 first contact unit
26 second contact unit
28 terminal connector
29 casting compound
30 first side
32 second side
34 control terminal
36 sintered connection
38 second control terminal
40 second terminal connector

1. A semiconductor package for a power semiconductor module in a power converter comprising:
a power semiconductor with a first side and an opposing second side, with a control terminal on the first side;
a first contact unit configured to obtain contact to the first side, wherein the first contact unit is in thermal and electrical contact with a majority of a surface on the first side;
a second contact unit configured to obtain contact to the second side, wherein the second contact unit is in thermal and electrical contact with a majority of a surface on the second side; and
a terminal connector configured to connect the control terminal on the power semiconductor to a control unit.

2. The semiconductor package according to claim 1,
wherein the semiconductor package contains no more than two power semiconductors.

3. The semiconductor package according to claim 1,
wherein the semiconductor package is encased in a casting compound.

4. The semiconductor package according to claim 1,
wherein the first contact unit is formed by a metallic layer, or is a rigid component, and/or wherein the second contact unit is a rigid component.

5. The semiconductor package according to claim 1,
wherein the first contact unit is in surface contact with at least 60% of the surface on the first side of the power semiconductor, and/or
wherein the second contact unit is in surface contact with an entirety of the surface on the second side of the power semiconductor.

6. The semiconductor package according to claim 1,
wherein the terminal connector comprises a flexible printed circuit board with a conductor path.

7. The semiconductor package according to claim 1,
wherein a sintered connection is formed between the first contact unit and the first side of the power semiconductor, and/or between the second contact unit and the second side of the power semiconductor.

8. The semiconductor package according to claim 1,
wherein a cross section of the first contact unit parallel to a plane of the power semiconductor where the first contact unit is in contact with the first side of the power semiconductor is smaller than in a part at a distance thereto, and a change in a size of the cross section is discrete.

9. The semiconductor package according to claim 1,
wherein the power semiconductor has a second control terminal on the first side, and the terminal connector forms a contact between the second control terminal and the control unit.

10. The semiconductor package according to claim 1,
wherein the semiconductor package does not have a flat insulating layer for insulating a majority of the first side of the power semiconductor and/or a majority of the second side of the power semiconductor.

11. A power semiconductor module for a power converter comprising:
a plurality of the semiconductor packages according to claim 1,
wherein a first half of the plurality of the semiconductor packages is preferably rotated 180° in relation to a second half of the plurality of the semiconductor packages, such that the first contact units on the first half of the plurality of the semiconductor packages face a same direction as second contact units on the second half of the plurality of the semiconductor packages.

12. A method for producing a plurality of semiconductor packages, the method comprising:
providing a support structure composed of an electrically and thermally conductive material;
populating the support structure with a plurality of power semiconductors, and obtaining electrical and thermal contact between second sides of the power semiconductors and the support structure;
dividing the support structure to obtain a plurality of semiconductor packages that each have no more than two power semiconductors; and
determining an electrical parameter for each of the semiconductor packages in a testing process, and sorting the semiconductor packages based on these parameters.

13. The method according to claim 12, comprising:
encasing the semiconductor packages in a casting compound.

14. The method according to claim 12, comprising:
forming a first contact unit by a metallic layer or a rigid component, and/or
forming a second contact unit by a rigid component.

15. The method according to claim 12, comprising:
causing a first contact unit to be in surface contact with at least 60% of a surface on a first side of the power semiconductor, and/or
causing a second contact unit to be in surface contact with an entirety of a surface on the second side of the power semiconductor.

16. The method according to claim 12,
wherein a terminal connector comprises a flexible printed circuit board with a conductor path.

17. The method according to claim 12, comprising:
forming a sintered connection between a first contact unit and a first side of the power semiconductor, and/or between a second contact unit and the second side of the power semiconductor.

18. The method according to claim 12, comprising:
forming a contact between a second control terminal on a first side of the power semiconductor and a control unit.

19. The method according to claim 12,
wherein the semiconductor package does not have a flat insulating layer for insulating a majority of a first side of the power semiconductor and/or a majority of the second side of the power semiconductor.
